(19) United States
(12) Patent Application Publication
(10) Pub. No.: US 2023/0178338 A1
(43) Pub. Date: Jun. 8, 2023

(54) PLASMA PROCESSING APPARATUS

(71) Applicant: TOKYO ELECTRON LIMITED, Tokyo (JP)

(72) Inventor: Hiroshi OTOMO, Yamanashi (JP)

(21) Appl. No.: 18/073,203

(22) Filed: Dec. 1, 2022

(30) Foreign Application Priority Data
Dec. 3, 2021 (JP) 2021196876

(51) Int. Cl. H01J 37/32

(52) U.S. Cl. CPC H01J 37/32183; H01J 37/32568; H01J 2237/327

(57) ABSTRACT

There is provided a plasma processing apparatus comprising: a chamber; a lower electrode provided in the chamber and included in a substrate support; an upper electrode provided in the chamber and disposed to face the lower electrode; a gas supply configured to supply a processing gas; a high-frequency power supply electrically connected to the upper electrode and configured to generate a plasma of the processing gas by applying a high-frequency voltage to the upper electrode; a first meter configured to measure a potential waveform of the upper electrode; a second meter configured to measure a potential waveform of the lower electrode; a detector configured to detect a voltage waveform; an impedance adjusting device configured to adjust an impedance of the lower electrode; and a controller configured to control the impedance adjusting device to adjust the impedance of the lower electrode based on the voltage waveform detected by the detector.

### CROSS-REFERENCE TO RELATED APPLICATIONS

This application claims priority to Japanese Patent Application No. 2021-196876 filed on Dec. 3, 2021, the entire contents of which are incorporated herein by reference.

### TECHNICAL FIELD

An exemplary embodiment of the present disclosure relates to a plasma processing apparatus.

### BACKGROUND

Plasma processing is performed as a type of substrate processing. In plasma processing, a substrate is processed with chemical species from a plasma generated in a chamber by high-frequency waves. Chemical species in plasma include ions and radicals. A substrate on a stage can be damaged by ion energy imparted by the high-frequency waves. The ion energy can be increased or decreased depending on the impedance value of a lower electrode (a stage with a lower electrode). Japanese Laid-open Patent Publication No. 2015-198084 discloses a technology for suppressing reflected waves to a high-frequency power supply by matching the impedances of the high-frequency power supply and a load side of the high-frequency power supply.

### SUMMARY

The present disclosure provides a technology for suitably adjusting the energy of ions that are generated during plasma generation and directed toward a lower electrode.

In accordance with an aspect of the present disclosure, there is provided a plasma processing apparatus comprising: a chamber; a lower electrode provided in the chamber and included in a substrate support configured to place a substrate thereon; an upper electrode provided in the chamber and disposed to face the lower electrode; a gas supply configured to supply a processing gas between the upper electrode and the lower electrode; a high-frequency power supply electrically connected to the upper electrode and configured to generate a plasma of the processing gas by applying a high-frequency voltage to the upper electrode; a first meter configured to measure a potential waveform of the upper electrode; a second meter configured to measure a potential waveform of the lower electrode; a detector configured to detect a voltage waveform obtained by subtracting a second potential waveform measured by the second meter from a first potential waveform measured by the first meter; an impedance adjusting device configured to adjust an impedance of the lower electrode; and a controller configured to control the impedance adjusting device to adjust the impedance of the lower electrode based on the voltage waveform detected by the detector.

### BRIEF DESCRIPTION OF THE DRAWINGS

FIG. 1 is a diagram showing a configuration of a plasma processing apparatus according to one exemplary embodiment.

FIG. 2 is a diagram showing a configuration of an exemplary impedance adjusting device.

FIG. 3 is a diagram showing another configuration of the exemplary impedance adjusting device.

### DETAILED DESCRIPTION

Hereinafter, various exemplary embodiments will be described.

In one exemplary embodiment, a plasma processing apparatus is provided. The plasma processing apparatus comprises a chamber, a lower electrode, an upper electrode, a gas supply, a high-frequency power supply, a first meter, a second meter, a detector, an impedance adjusting device, and a controller. The lower electrode may be provided in the chamber and included in a substrate support configured to place a substrate thereon. The upper electrode may be provided in the chamber and disposed to face the lower electrode. The gas supply may be configured to supply a processing gas between the upper electrode and the lower electrode. The high-frequency power supply may be electrically connected to the upper electrode and configured to generate a plasma of the processing gas by applying a high-frequency voltage to the upper electrode. The first meter may be configured to measure a potential waveform of the upper electrode. The second meter may be configured to measure a potential waveform of the lower electrode. The detector may be configured to detect a voltage waveform obtained by subtracting a second potential waveform measured by the second meter from a first potential waveform measured by the first meter. The impedance adjusting device may be configured to adjust an impedance of the lower electrode. The controller may be configured to control the impedance adjusting device to adjust the impedance of the lower electrode based on the voltage waveform detected by the detector.

Therefore, the impedance of the lower electrode is adjusted according to the voltage waveform obtained by subtracting the second potential waveform of the lower electrode from the first potential waveform of the upper electrode, and thus the energy of ions directed toward the lower electrode generated during plasma generation can be adjusted. Since a sheath voltage on the lower electrode which provides energy to the ions is increased or decreased with a high correlation depending on the voltage between the upper electrode and the lower electrode, the energy of the ions can be optimized more than when the impedance of the lower electrode is adjusted based on a current flowing through the lower electrode. Particularly, since it becomes possible to adjust the lower sheath voltage on the lower electrode, the energy of ions in the loser energy region can be adjusted with high accuracy. Also, since the voltage waveform between the upper electrode and the lower electrode is used, the above configuration can also be applied to a plasma processing apparatus in which a plurality of power supplies are connected to each electrode.

In one exemplary embodiment, the controller may control the impedance adjusting device to adjust the impedance of the lower electrode so as to reduce a peak value on a positive potential side of the voltage waveform.

In one exemplary embodiment, the impedance adjusting device may have a capacitor and an inductor. At least one of a capacitance of the capacitor and an inductance of the inductor may be variable and may be controlled by the controller. The capacitor and the inductor may be electrically connected in series. The capacitor may be electrically connected to the lower electrode. The inductor may be electrically connected to the lower electrode via the capacitor.

In one exemplary embodiment, the impedance adjusting device may have a first capacitor, a second capacitor, and an inductor. At least one of a first capacitance of the first capacitor, a second capacitance of the second capacitor, and an inductance of the inductor may be variable and may be controlled by the controller. The first capacitor and the inductor may be electrically connected in series. The first capacitor may be electrically connected to the lower electrode. The inductor may be electrically connected to the lower electrode via the first capacitor. The second capacitor and the inductor may be electrically connected in parallel to the lower electrode via the first capacitor.

In one exemplary embodiment, the impedance adjusting device may have a plurality of electrical circuits electrically connected in parallel to the lower electrode. Each of the plurality of electrical circuits may have a capacitor and an inductor. In each of the plurality of electrical circuits, at least one of a capacitance of the capacitor and an inductance of the inductor may be variable and may be controlled by the controller. In each of the plurality of electrical circuits, the capacitor and the inductor may be electrically connected in series. In each of the plurality of electrical circuits, the capacitor may be electrically connected to the lower electrode. In each of the plurality of electrical circuits, the inductor may be electrically connected to the lower electrode via the capacitor.

In one exemplary embodiment, the impedance adjusting device may have a plurality of electrical circuits electrically connected in parallel to the lower electrode. Each of the plurality of electrical circuits may have a first capacitor, a second capacitor, and an inductor. In each of the plurality of electrical circuits, at least one of a capacitance of the first capacitor, a capacitance of the second capacitor, and an inductance of the inductor may be variable and may be controlled by the controller. In each of the plurality of electrical circuits, the first capacitor and the inductor may be electrically connected in series. In each of the plurality of electrical circuits, the first capacitor may be electrically connected to the lower electrode. In each of the plurality of electrical circuits, the inductor may be electrically connected to the lower electrode via the first capacitor. In each of the plurality of electrical circuits, the second capacitor and the inductor may be electrically connected in parallel to the lower electrode via the first capacitor.

In one exemplary embodiment, each of the plurality of electrical circuits may have the capacitor with different capacitance and the inductor with different inductance.

In one exemplary embodiment, each of the plurality of electrical circuits may have the first capacitor with different capacitance, the second capacitor with different capacitance, and the inductor with different inductance.

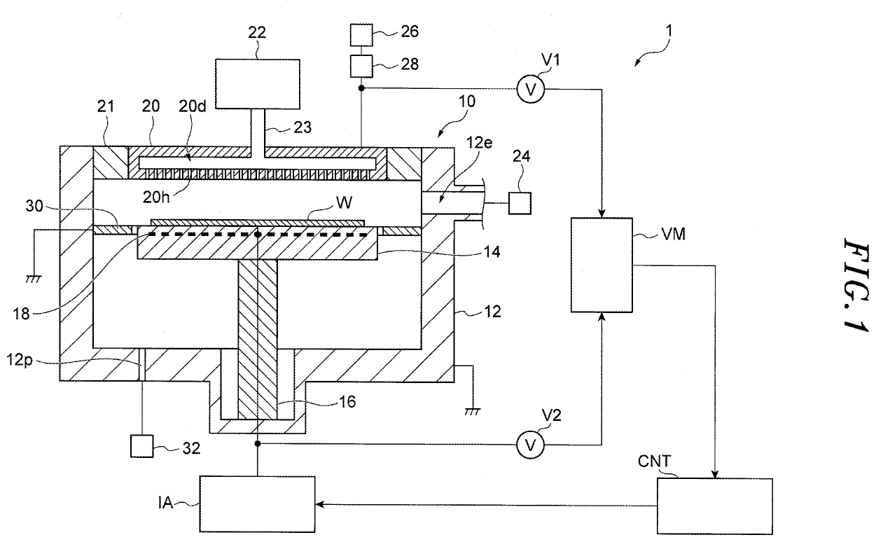

Hereinafter, various exemplary embodiments will be described in detail with reference to the drawings. Also, in each drawing, the same reference numeral is attached to the component which is the same or equivalent. FIG. 1 is a schematic diagram of a plasma processing apparatus according to one exemplary embodiment. The plasma processing apparatus 1 shown in FIG. 1 includes a chamber 10. The chamber 10 provides an inner space therein. The chamber 10 may include a chamber body 12. The chamber body 12 has a substantially cylindrical shape. The inner space of the chamber 10 is provided within the chamber body 12. The chamber body 12 is made of metal such as aluminum. The chamber body 12 is electrically grounded. A sidewall of the chamber body 12 may provide a passage through which a substrate W is transferred. Also, a gate valve may be provided along the sidewall of the chamber body 12 to open and close this passage.

The plasma processing apparatus 1 further includes a substrate support 14. The substrate support 14 is installed inside the chamber 10. The substrate support 14 is configured to support the substrate W placed thereon. The substrate support 14 has a main body. The main body of the substrate support 14 is made of, for example, aluminum nitride, and may have a disc shape. The substrate support 14 may be supported by a support member 16. The support member 16 extends upwardly from the bottom of the chamber 10. The substrate support 14 includes a lower electrode 18. The substrate support 14 may be provided within the chamber 10 (chamber body 12) and configured to place the substrate W thereon. The lower electrode 18 is included in the substrate support 14 and is embedded with the main body of the substrate support 14.

The plasma processing apparatus 1 further includes an upper electrode 20. The upper electrode 20 is provided inside the chamber 10 and above the substrate support 14. The upper electrode 20 is disposed so as to face the lower electrode 18. The upper electrode 20 constitutes a ceiling portion of the chamber 10. The upper electrode 20 is electrically separated from the chamber body 12. In one embodiment, the upper electrode 20 is fixed to the top of the chamber body 12 via an insulating member 21.

In one embodiment, the upper electrode 20 is configured as a shower head. The upper electrode 20 provides a gas diffusion space 20d therein. Also, the upper electrode 20 further provides a plurality of gas holes 20h. The plurality of gas holes 20h extend downward from the gas diffusion space 20d and open toward the inner space of the chamber 10. That is, the plurality of gas holes 20h connect the gas diffusion space 20d and the inner space of the chamber 10.

The plasma processing apparatus 1 further includes a gas supply 22. The gas supply 22 is configured to supply gas into the chamber 10. The gas supply 22 is configured to supply a processing gas between the upper electrode 20 and the lower electrode 18. The gas supply 22 is connected to the gas diffusion space 20d through a pipe 23. The gas supply 22 may have one or more gas sources, one or more flow controllers, and one or more on/off valves. Each of the one or more gas sources is connected to the pipe 23 via a corresponding flow controller and a corresponding on/off valve.

In one embodiment, the gas supply 22 may supply a film forming gas. That is, the plasma processing apparatus 1 may be a film forming apparatus. A film formed on the substrate W using the film forming gas may be an insulating film. In another embodiment, the gas supply 22 may supply an etching gas. That is, the plasma processing apparatus 1 may be a plasma etching apparatus.

The plasma processing apparatus 1 further includes an exhaust device 24. The exhaust device 24 includes a pressure controller, such as an automatic pressure control valve, and a vacuum pump, such as a turbomolecular pump or a dry pump. The exhaust device 24 is connected to the inner space of the chamber 10 via an exhaust pipe from an exhaust port 12e provided on the sidewall of the chamber body 12.

The plasma processing apparatus 1 further includes a high-frequency power supply 26. The high-frequency power supply 26 is electrically connected to the upper electrode 20 via a matching device 28. The high-frequency power supply 26 may be configured to include the matching device 28. The high-frequency power supply 26 is configured to apply a high-frequency voltage to the upper electrode 20 to generate a plasma of the processing gas supplied from the gas supply 22 between the upper electrode 20 and the lower electrode 18. In one embodiment, the high-frequency power supply 26 generates high-frequency power. The frequency of the high-frequency power may be any frequency. The frequency of the high-frequency power may be 13.56 MHz or lower. The frequency of the high-frequency power may be 2 MHz or lower. The frequency of the high-frequency power may be 20 kHz or higher.

The high-frequency power supply 26 is connected to the upper electrode 20 via the matching device 28. The high-frequency power from the high-frequency power supply 26 is supplied to the upper electrode 20 via the matching device 28. The matching device 28 has a matching circuit for matching the impedance of a load of the high-frequency power supply 26 with an output impedance of the high-frequency power supply 26.

In another embodiment, the high-frequency power supply 26 may be configured to periodically apply pulses of DC voltage to the upper electrode 20. A frequency for defining a cycle of applying the pulses of DC voltage from the high-frequency power supply 26 to the upper electrode 20 is, for example, 10 kHz or higher and 10 MHz or lower. Also, if the high-frequency power supply 26 is configured to periodically apply the pulses of DC voltage to the upper electrode 20, the plasma processing apparatus 1 may not include the matching device 28.

The plasma processing apparatus 1 further includes a ring electrode 30. The ring electrode 30 has an annular shape. The ring electrode 30 may be divided into a plurality of electrodes arranged along the circumferential direction. The ring electrode 30 is provided around the substrate support 14 so as to surround an outer periphery of the substrate support 14. A gap is provided between the ring electrode 30 and the outer periphery of the substrate support 14, but the gap may not be provided. The ring electrode 30 is electrically grounded.

In one embodiment, the plasma processing apparatus 1 further includes a gas supply 32. The gas supply 32 supplies a purge gas so that the purge gas flows upward through the gap between the ring electrode 30 and the substrate support 14. The gas supply 32 supplies the purge gas into the chamber 10 through a gas introduction port 12p. In the illustrated example, the gas introduction port 12p is provided on a wall of the chamber body 12 below the substrate support 14. The purge gas supplied by the gas supply 32 may be an inert gas or a rare gas, for example.

When plasma processing is performed on the substrate W in the plasma processing apparatus 1, the processing gas is supplied into the chamber 10 from the gas supply 22. Also, the high-frequency power or the pulse of DC voltage from the high-frequency power supply 26 is applied to the upper electrode 20. As a result, a plasma is generated from the processing gas within the chamber 10. The substrate W on the substrate support 14 is processed with chemical species from the generated plasma. For example, the chemical species from the plasma form a film on the substrate W. Alternatively, the chemical species from the plasma etch the substrate W.

In one embodiment, the plasma processing apparatus 1 further includes a meter V1, a meter V2, a detector VM, and an impedance adjusting device IA. The meter V1 is configured to measure a potential waveform of the upper electrode 20. The meter V2 is configured to measure a potential waveform of the lower electrode 18. The detector VM is configured to detect a voltage waveform obtained by subtracting a second potential measured by the meter V2 from a first potential waveform measured by the meter V1. The impedance adjusting device IA is configured to adjust the impedance of the lower electrode 18.

In one embodiment, the plasma processing apparatus 1 further includes a controller CNT. The controller CNT is configured to control the impedance adjusting device IA to adjust the impedance of the lower electrode 18 based on the voltage waveform detected by the detector VM. The controller CNT controls the impedance adjusting device IA to adjust the impedance of the lower electrode 18 so as to reduce a peak value on a positive potential side of the voltage waveform detected by the detector VM.

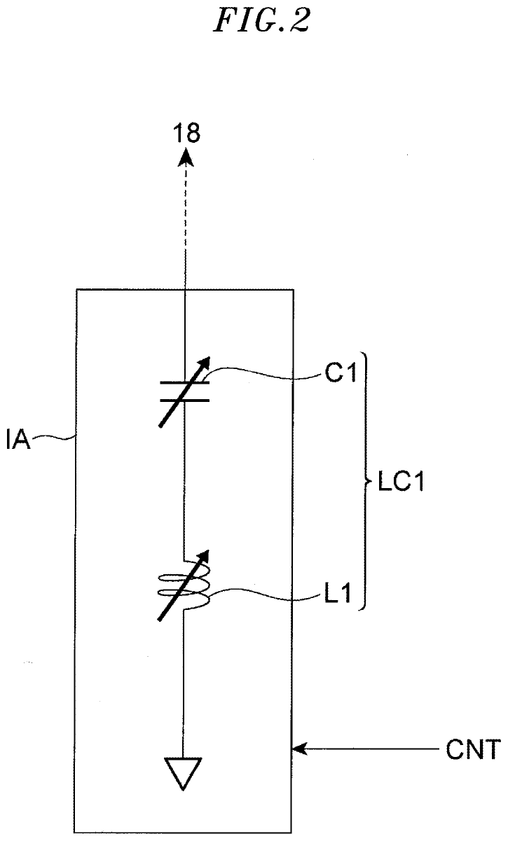

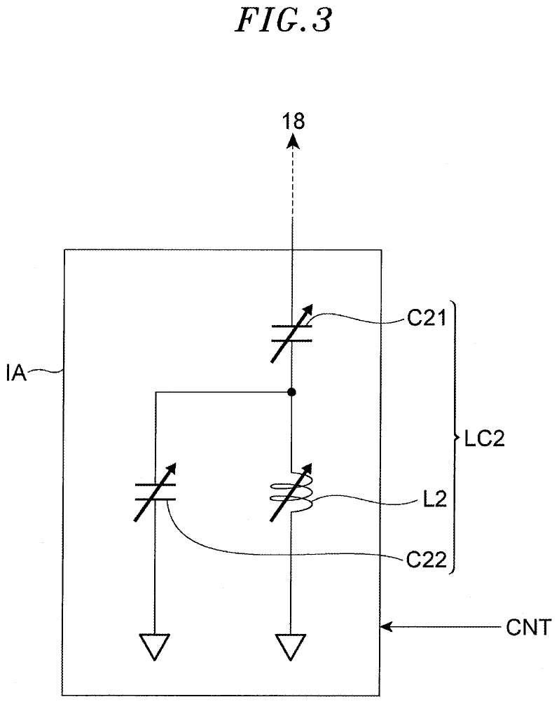

A configuration of the impedance adjusting device IA will be described with reference to FIGS. 2 and 3.

FIG. 2 shows a configuration of the impedance adjusting device IA according to one example. The impedance adjusting device IA shown in FIG. 2 has an electrical circuit LC1. The electrical circuit LC1 has a capacitor C1 and an inductor L1. At least one of a capacitance of the capacitor C1 and an inductance of the inductor L1 is variable and can be controlled by the controller CNT. The capacitor C1 and the inductor L1 are electrically connected in series. The capacitor C1 is electrically connected to the lower electrode 18. The inductor L1 is electrically connected to the lower electrode 18 via the capacitor C1.

According to the impedance adjusting device IA shown in FIG. 2, the electrical circuit LC1 in which the capacitor C1 and the inductor L1 are electrically connected in series enables the substrate support 14 to have a high impedance in the vicinity of an excitation frequency that generates plasma by a resonance phenomenon and in a DC component. Since the electrical circuit LC1 is an LC series resonance circuit, it has a low impedance when it resonates, however, since a parasitic capacitance of the substrate support 14 is electrically connected in parallel to the electrical circuit LC1, the substrate support 14 has a high impedance.

FIG. 3 shows a configuration of the impedance adjusting device IA according to one example. The impedance adjusting device IA shown in FIG. 3 has an electrical circuit LC2. The electrical circuit LC2 has a capacitor C21, a capacitor C22, and an inductor L2. At least one of a first capacitance of the capacitor C21, a second capacitance of the capacitor C22, and an inductance of the inductor L2 is variable and can be controlled by the controller CNT. The capacitor C21 and the inductor L2 are electrically connected in series. The capacitor C21 and the capacitor C22 are electrically connected in series. The capacitor C21 is electrically connected to the lower electrode 18. The inductor L2 is electrically connected to the lower electrode 18 via the capacitor C21. The capacitor C22 and the inductor L2 are electrically connected in parallel to the lower electrode 18 via the capacitor C21.

According to the impedance adjusting device IA shown in FIG. 3, the electrical circuit LC2 in which the capacitor C22 and the inductor L2 are electrically connected in parallel enables the substrate support 14 to have a high impedance in the DC component and in the vicinity of the excitation frequency. The capacitor C21 of the electrical circuit LC2 is provided to cut the DC component. An LC parallel resonance circuit (circuit consisting only of the inductor L2 and the capacitor C22) may be provided as an LC circuit of the impedance adjusting device IA. In this case, the impedance of the substrate support 14 can be high in the vicinity of the excitation frequency that generates a plasma by the resonance phenomenon, but the impedance of the substrate support 14 is low in the DC component. Therefore, the substrate support 14 can have a high impedance in the DC component as well, by providing the capacitor C21 in the preceding stage of the LC parallel resonance circuit (circuit consisting only of the inductor L2 and the capacitor C22) as in the electrical circuit LC2.

The impedance adjusting device IA may have a plurality of electrical circuits LC1 shown in FIG. 2 to accommodate superposition of high-frequency waves or superposition of power frequencies. In this case, the impedance adjusting device IA has a plurality of electrical circuits LC1 electrically connected in parallel to the lower electrode 18. Each of the plurality of electrical circuits LC1 includes the capacitor C1 and the inductor L1. In each of the plurality of electrical circuits LC1, at least one of the capacitance of the capacitor C1 and the inductance of the inductor L1 is variable and can be controlled by the controller CNT. In each of the plurality of electrical circuits LC1, the capacitor C1 and the inductor L1 are electrically connected in series. In each of the plurality of electrical circuits LC1, the capacitor C1 is electrically connected to the lower electrode 18. In each of the plurality of electrical circuits LC1, the inductor L1 is electrically connected to the lower electrode 18 via the capacitor C1. Each of the plurality of electrical circuits LC1 may have the capacitor C1 with different capacitance and the inductor L1 with different inductance.

For example, if the impedance adjusting device IA has two electrical circuits LC1 electrically connected with each other in parallel, the substrate support 14 can have a high impedance at two frequencies. For example, if the impedance adjusting device IA has three electrical circuits LC1 electrically connected with each other in parallel, the substrate support 14 can have a high impedance at three frequencies. If the impedance adjusting device IA has more electrical circuits LC1 electrically connected with each other in parallel, the substrate support 14 can have a high impedance at more frequencies.

The impedance adjusting device IA may have a plurality of electrical circuits LC2 shown in FIG. 3 to accommodate superposition of high frequency waves or superposition of power frequencies. In this case, the impedance adjusting device IA has a plurality of electrical circuits LC2 electrically connected in parallel to the lower electrode 18. Each of the plurality of electrical circuits LC2 includes the capacitor C21, the capacitor C22, and the inductor L2. In each of the plurality of electrical circuits LC2, at least one of the capacitance of the capacitor C21, the capacitance of the capacitor C22, and the inductance of the inductor L2 is variable and can be controlled by the controller CNT. In each of the plurality of electrical circuits LC2, the capacitor C21 and the inductor L2 are electrically connected in series. In each of the plurality of electrical circuits LC2, the capacitor C21 and the capacitor C22 are electrically connected in series. In each of the plurality of electrical circuits LC2, the capacitor C21 is electrically connected to the lower electrode 18. In each of the plurality of electrical circuits LC2, the inductor L2 is electrically connected to the lower electrode 18 via the capacitor C21. In each of the plurality of electrical circuits LC2, the capacitor C22 and the inductor L2 are electrically connected in parallel to the lower electrode 18 via the capacitor C21. Each of the plurality of electrical circuits LC2 may have the capacitor C21 with different capacitance, the capacitor C22 with different capacitance, and the inductor L2 with different inductance.

For example, if the impedance adjusting device IA has two electrical circuits LC2 electrically connected with each other in parallel, the substrate support 14 can have a high impedance at two frequencies. For example, if the impedance adjusting device IA has three electrical circuits LC2 electrically connected with each other in parallel, the substrate support 14 can have a high impedance at three frequencies. If the impedance adjusting device IA has more electrical circuits LC2 electrically connected with each other in parallel, the substrate support 14 can have a high impedance at more frequencies.

As described above, by using the LC circuits (the electrical circuit LC1 and the electrical circuit LC2) shown in each of FIGS. 2 and 3 for the impedance adjusting device IA, the impedance of the substrate support 14 can be adjusted in the vicinity of an excitation frequency that generates a plasma by a resonance phenomenon. Generally, when the impedance of the substrate support 14 including the lower electrode 18 is high, the plasma is concentrated on the upper electrode 20 and the sidewall of the chamber body 12, so the energy of ions directed toward the substrate support 14 can be adjusted to be low. At this time, the impedance of the lower electrode 18 can be made infinite by setting the lower electrode 18 to an electrically open state. However, parasitic capacitance generated in the substrate support 14 including the lower electrode 18 causes the substrate support 14 to be electrically coupled to GND. In this case, it may not be possible to obtain the desired effect of lowering the energy of ions directed toward the substrate support 14. Therefore, by making a part of the LC circuits (the electrical circuit LC1 and the electrical circuit LC2) variable, it is possible to effectively adjust the impedance of the substrate support 14 including the parasitic capacitance of the substrate support 14. Also, in the case of the electrical circuit LC2 shown in FIG. 3, a DC bias can be cut by placing the capacitor C21 between the LC circuit and the lower electrode 18 so as to be electrically parallel to the parasitic capacitance of the substrate support 14. The configuration of the impedance adjusting device IA is not limited to the configuration shown in each of FIGS. 2 and 3, and the impedance adjusting device IA may have other configurations as long as the same effects can be achieved.

According to the plasma processing apparatus 1 having the above configuration, the impedance of the lower electrode 18 is adjusted according to the voltage waveform obtained by subtracting the second potential waveform of the lower electrode 18 from the first potential waveform of the upper electrode 20. Thereby, the energy of ions directed toward the lower electrode 18 generated during plasma generation can be adjusted. A sheath voltage on the lower electrode 18, which provides energy to the ions, is increased or decreased depending on the voltage between the upper electrode 20 and the lower electrode 18 in a highly correlated manner. Thus, the energy of the ions can be optimized more than when the impedance of the lower electrode 18 is adjusted based on a current flowing through the lower electrode 18. Particularly, since the lower sheath voltage on the lower electrode 18 can be adjusted, the energy of ions in the lower energy region can be adjusted with high accuracy. Also, since the voltage waveform between the upper electrode 20 and the lower electrode 18 is used, the above configuration can also be applied to a plasma processing apparatus in which a plurality of power supplies are connected to each electrode.

While various exemplary embodiments have been described above, various additions, omissions, substitutions, and modifications may be made without being limited to the exemplary embodiments described above. Further, elements from different embodiments can be combined to form another embodiment.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A plasma processing apparatus comprising:
a chamber;
a lower electrode provided in the chamber and included in a substrate support configured to place a substrate thereon;
an upper electrode provided in the chamber and disposed to face the lower electrode;
a gas supply configured to supply a processing gas between the upper electrode and the lower electrode;
a high-frequency power supply electrically connected to the upper electrode and configured to generate a plasma of the processing gas by applying a high-frequency voltage to the upper electrode;
a first meter configured to measure a potential waveform of the upper electrode;
a second meter configured to measure a potential waveform of the lower electrode;
a detector configured to detect a voltage waveform obtained by subtracting a second potential waveform measured by the second meter from a first potential waveform measured by the first meter;
an impedance adjusting device configured to adjust an impedance of the lower electrode; and
a controller configured to control the impedance adjusting device to adjust the impedance of the lower electrode based on the voltage waveform detected by the detector.

2. The plasma processing apparatus of claim 1, wherein the controller controls the impedance adjusting device to adjust the impedance of the lower electrode so as to reduce a peak value on a positive potential side of the voltage waveform.

3. The plasma processing apparatus of claim 1, wherein the impedance adjusting device has a capacitor and an inductor,
at least one of a capacitance of the capacitor and an inductance of the inductor is variable and controlled by the controller,
the capacitor and the inductor are electrically connected in series,
the capacitor is electrically connected to the lower electrode, and
the inductor is electrically connected to the lower electrode via the capacitor.

4. The plasma processing apparatus of claim 2, wherein the impedance adjusting device has a capacitor and an inductor,
at least one of a capacitance of the capacitor and an inductance of the inductor is variable and controlled by the controller,
the capacitor and the inductor are electrically connected in series,
the capacitor is electrically connected to the lower electrode, and
the inductor is electrically connected to the lower electrode via the capacitor.

5. The plasma processing apparatus of claim 1, wherein the impedance adjusting device has a first capacitor, a second capacitor, and an inductor,
at least one of a first capacitance of the first capacitor, a second capacitance of the second capacitor, and an inductance of the inductor is variable and controlled by the controller,
the first capacitor and the inductor are electrically connected in series,
the first capacitor is electrically connected to the lower electrode,
the inductor is electrically connected to the lower electrode via the first capacitor, and
the second capacitor and the inductor are electrically connected in parallel to the lower electrode via the first capacitor.

6. The plasma processing apparatus of claim 2, wherein the impedance adjusting device has a first capacitor, a second capacitor, and an inductor,
at least one of a first capacitance of the first capacitor, a second capacitance of the second capacitor, and an inductance of the inductor is variable and controlled by the controller,
the first capacitor and the inductor are electrically connected in series,
the first capacitor is electrically connected to the lower electrode,
the inductor is electrically connected to the lower electrode via the first capacitor, and
the second capacitor and the inductor are electrically connected in parallel to the lower electrode via the first capacitor.

7. The plasma processing apparatus of claim 1, wherein the impedance adjusting device has a plurality of electrical circuits electrically connected in parallel to the lower electrode,
each of the plurality of electrical circuits includes a capacitor and an inductor,
in each of the plurality of electrical circuits, at least one of a capacitance of the capacitor and an inductance of the inductor is variable and controlled by the controller,
in each of the plurality of electrical circuits, the capacitor and the inductor are electrically connected in series,
in each of the plurality of electrical circuits, the capacitor is electrically connected to the lower electrode, and
in each of the plurality of electrical circuits, the inductor is electrically connected to the lower electrode via the capacitor.

8. The plasma processing apparatus of claim 2, wherein the impedance adjusting device has a plurality of electrical circuits electrically connected in parallel to the lower electrode,
each of the plurality of electrical circuits includes a capacitor and an inductor,
in each of the plurality of electrical circuits, at least one of a capacitance of the capacitor and an inductance of the inductor is variable and controlled by the controller,
in each of the plurality of electrical circuits, the capacitor and the inductor are electrically connected in series,
in each of the plurality of electrical circuits, the capacitor is electrically connected to the lower electrode, and
in each of the plurality of electrical circuits, the inductor is electrically connected to the lower electrode via the capacitor.

9. The plasma processing apparatus of claim 1, wherein the impedance adjusting device has a plurality of electrical circuits electrically connected in parallel to the lower electrode,
each of the plurality of electrical circuits has a first capacitor, a second capacitor, and an inductor,
in each of the plurality of electrical circuits, at least one of a capacitance of the first capacitor, a capacitance of the second capacitor, and an inductance of the inductor is variable and controlled by the controller,
in each of the plurality of electrical circuits, the first capacitor and the inductor are electrically connected in series,
in each of the plurality of electrical circuits, the first capacitor is electrically connected to the lower electrode,
in each of the plurality of electrical circuits, the inductor is electrically connected to the lower electrode via the first capacitor, and
in each of the plurality of electrical circuits, the second capacitor and the inductor are electrically connected in parallel to the lower electrode via the first capacitor.

10. The plasma processing apparatus of claim 2, wherein the impedance adjusting device has a plurality of electrical circuits electrically connected in parallel to the lower electrode,
each of the plurality of electrical circuits has a first capacitor, a second capacitor, and an inductor,
in each of the plurality of electrical circuits, at least one of a capacitance of the first capacitor, a capacitance of the second capacitor, and an inductance of the inductor is variable and controlled by the controller,
in each of the plurality of electrical circuits, the first capacitor and the inductor are electrically connected in series,
in each of the plurality of electrical circuits, the first capacitor is electrically connected to the lower electrode,
in each of the plurality of electrical circuits, the inductor is electrically connected to the lower electrode via the first capacitor, and
in each of the plurality of electrical circuits, the second capacitor and the inductor are electrically connected in parallel to the lower electrode via the first capacitor.

11. The plasma processing apparatus of claim 7, wherein each of the plurality of electrical circuits has the capacitor with different capacitance and the inductor with different inductance.

12. The plasma processing apparatus of claim 8, wherein each of the plurality of electrical circuits has the capacitor with different capacitance and the inductor with different inductance.

13. The plasma processing apparatus of claim 9, wherein each of the plurality of electrical circuits has the first capacitor with different capacitance, the second capacitor with different capacitance, and the inductor with different inductance.

14. The plasma processing apparatus of claim 10, wherein each of the plurality of electrical circuits has the first capacitor with different capacitance, the second capacitor with different capacitance, and the inductor with different inductance.
